(19) United States
(12) Patent Application Publication
(10) Pub. No.: US 2006/0086983 A1
(43) Pub. Date: Apr. 27, 2006

(54) Electrostatic protective element of semiconductor integrated circuit

(75) Inventor: Masakatsu Nawate, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/195,651

(22) Filed: Aug. 3, 2005

(30) Foreign Application Priority Data
Oct. 27, 2004 (JP) P2004-312549

(51) Int. Cl. H01L 23/62

(52) U.S. Cl. 257/355

(57) ABSTRACT

An electrostatic protective element of the present invention comprises: a second-conductive-type and lightly-doped first diffusion layer to be a collector, which is formed to be in contact with a first conductive type semiconductor substrate; a first-conductive-type second diffusion layer to be a base, which is formed on the first diffusion layer; a second-conductive-type third diffusion layer to be an emitter, which is formed on the second diffusion layer, wherein the bottom face of the first diffusion layer is in contact with the semiconductor substrate. Further, the electrostatic protective element comprises a second-conductive-type and heavily-doped fourth diffusion layer, which is formed deeper than the second diffusion layer in a contact area of the first diffusion layer.

### BACKGROUND OF THE INVENTION

1. Field of the Invention

The present invention relates to an electrostatic protective element of a semiconductor integrated circuit and, more specifically, to an electrostatic protective element formed of a bipolar transistor.

2. Description of the Related Art

ESD (Electro Static Discharge) protective elements are used for protecting semiconductor integrated circuits from static electricity. For example, in FIG. 8, protective diodes 25, 26, and 27 protect transistors and the like within an internal circuit 21 from overvoltage through breakdown when a high voltage by static electricity is applied between each terminal. Further, a protective transistor 28 breaks down at a voltage lower than that of the protective diode 27. This is to correspond to the reduced junction area due to micronization of the process and deterioration in breaking strength in accordance with reduction of the wiring width. The protective diode 27 alone does not function effectively.

By referring to FIG. 9, snapback action of an NPN transistor will be described. When a surge voltage is applied to a collector electrode, it is broken down between the collector and a base (BVcbo). Then, the base potential boosts up reaching an ON-voltage of the transistor so that the transistor starts to operate (snapback start point: (Vt1, It1)). When the snapback action is started, the collector potential decreases to DC withstand voltage (BVceo) between the collector and an emitter (maintaining point: (Vh, Ih). Then, in accordance with the ON-resistance of the transistor, the collector potential continues to boost up until ESD breakdown voltage Vt2. Generation of heat within the transistor causes thermal runaway, which results in breakdown (secondary breaking point: (Vt2, It2)).

Normally, the diffusion structure of the protective transistor is the same as that of the NPN transistor of a circuit to be protected. If the DC withstand voltage BVceo of the transistor is lower than a rated voltage of the circuit to be protected, the maintaining voltage Vh also becomes lower than the rated voltage of the circuit to be protected. Thus, the circuit to be protected breaks down by the overcurrent.

Now, let's look into a BiMOS-type semiconductor integrated circuit comprising both a high-breakdown-strength MOS transistor and a low-breakdown-strength NPN transistor. In the case where the low-breakdown-strength NPN transistor is used as the protective transistor for protecting the high-breakdown-strength MOS transistor from static electricity, the protective transistor is formed in a structure with no embedded diffusion layer for making it to have high breakdown strength. However, there are two problems in regards to the snapback characteristic. First, the collector concentration of the protective transistor becomes lower as mush as two digits so that the snapback action start voltage Vt1 is increased. Secondly, the NPN transistor is designed to have low breakdown strength so that the DC withstand voltage BVceo (=Vh) becomes low. Due to the multiplier of the above-described problems, breakdown is caused by the overcurrent at the time of snapback action.

### BRIEF SUMMARY OF THE INVENTION

In the description provided below regarding the conductive types of the semiconductor, the first conductive type and the second conductive type respectively indicate the semiconductor of either the P-type or N-type. When the first conductive type is the P-type, the second conductive type is the N-type. Inversely, when the first conductive type is the N-type, the second conductive type is the P-type.

The electrostatic protective element of a semiconductor integrated circuit according to the present invention is formed of a bipolar transistor, and comprises:

a second-conductive-type and lightly-doped first diffusion layer to be a collector, which is formed to be in contact with a first conductive type semiconductor substrate;

a first-conductive-type second diffusion layer to be a base, which is formed on the first diffusion layer;

a second-conductive-type third diffusion layer to be an emitter, which is formed on the second diffusion layer, wherein

the bottom face of the first diffusion layer is in contact with the semiconductor substrate. Further, it comprises a second-conductive-type and heavily-doped fourth diffusion layer, which is formed deeper than the second diffusion layer in a contact area of the first diffusion layer.

In this structure, the snapback action start voltage Vt1 and the maintaining voltage Vh are controlled by forming the second-conductive-type and heavily-doped fourth diffusion layer. That is, first, by forming the second-conductive-type and heavily-doped fourth diffusion layer on the second-conductive-type and lightly-doped first diffusion layer, the collector resistance is decreased. As a result, slant of the saturation area of Vc-Ic characteristic becomes large thereby decreasing the snapback action start voltage Vt1. Secondly, an increase in the collector current caused by the decrease in the collector resistance generates Kirk effect (base extruding effect) so that the base layer of the first-conductive-type second diffusion layer extends in the depth direction (in the direction of the substrate). When the base layer of the second diffusion layer reaches the semiconductor substrate, the first-conductive-type second diffusion layer, the second-conductive-type lightly-doped first diffusion layer, and the first-conductive-type semiconductor substrate function as the base layer. Thus, the emitter ground current amplification factor h_{FE} of the NPN transistor is decreased and the maintaining voltage Vt1 is increased. By the multiplier of the above-described effects, it is possible to achieve an electrostatic protective element with the lower snapback action start voltage Vt1 and the higher maintaining voltage Vh compared to those of the related art. Thus, it enables to improve the electrostatic protection effect for a circuit to be protected.

In addition, the electrostatic protective element of a semiconductor integrated circuit according to the present invention is the electrostatic protective element in the above-described structure, further comprising:

a diode whose anode is connected to the base of the bipolar transistor and whose cathode is connected to the collector of the bipolar transistor; and

a resistance connected between the base and the emitter of the bipolar transistor,

the electrostatic protective element being formed in a compound type having a combination of the bipolar transistor, the diode, and the resistance.

In this structure, the electrostatic protective element is considered to have indefinite number of small transistors being equivalently connected in parallel. When a surge voltage is applied, first, the transistor at the position where it is most difficult to take the base potential is start to operate, and then the transistors in other positions start the operation one after another. The electric current concentrates on the transistor which started the action in the first place and has become low resistant. Accordingly, the transistor which started the action in the first place goes into breakdown.

Thus, the diode is used to connect the base and the collector of the transistor for improving the uniformity of the actions of the transistors. Specifically, by adding the diode, the snapback action start voltage Vt1 is decreased while keeping the maintaining voltage Vh so as to make it lower than the ESD breakdown voltage Vt2. As a result, all the transistors perform the snapback action thereby dispersing the electric current so as to be uniformly flown to each transistor. Therefore, dispersion in the ESD breakdown resistance It2 becomes less and the ESD breakdown resistance can be further improved.

In any one of the structures described above, it is preferable that the fourth diffusion layer be formed deeper or almost in the same depth with respect to the first diffusion layer.

Further, it is preferable that the base of the bipolar transistor be connected to an input/output terminal or a power supply terminal of a circuit to be protected through the diode, the collector of the bipolar transistor be connected to the input/output terminal or the power supply terminal, and the emitter of the bipolar transistor be connected to a minimum potential terminal of the circuit to be protected.

Further, it is preferable that the diode be comprised of the first diffusion layer to be a cathode and the second diffusion layer to be an anode.

Furthermore, it is preferable that the diode comprise the heavily-doped fourth diffusion layer in the contact area of the first diffusion layer.

Additional objects and advantages of the present invention will be apparent from the following detailed description of preferred embodiments thereof, which are best understood with reference to the accompanying drawings.

### BRIEF DESCRIPTION OF THE DRAWINGS

FIG. 1 is a cross section of an electrostatic protective element in a first embodiment of the present invention;

FIG. 2 is a comparative graph for showing maintaining voltage Vh of the electrostatic protective element of the first embodiment of the present invention and that of an electrostatic protective element of a related art;

FIG. 3 is an illustration for showing the result of electric current simulation when Transmission line Pulse is applied to the electrostatic protective element according to the first embodiment of the present invention;

FIG. 4 is an illustration for showing the result of electric field simulation when TLP is applied to the electrostatic protective element according to the first embodiment of the present invention;

FIG. 5 is a cross section of a compound-type electrostatic protective element according to a second embodiment of the present invention;

FIG. 6 is an equivalent circuit diagram of the compound-type electrostatic protective element according to the second embodiment of the present invention;

FIG. 7 is a graph for showing the effect of the diode in the compound-type electrostatic protective element according to the second embodiment of the present invention;

FIG. 8 is a circuit diagram of an electrostatic protective element of the related art;

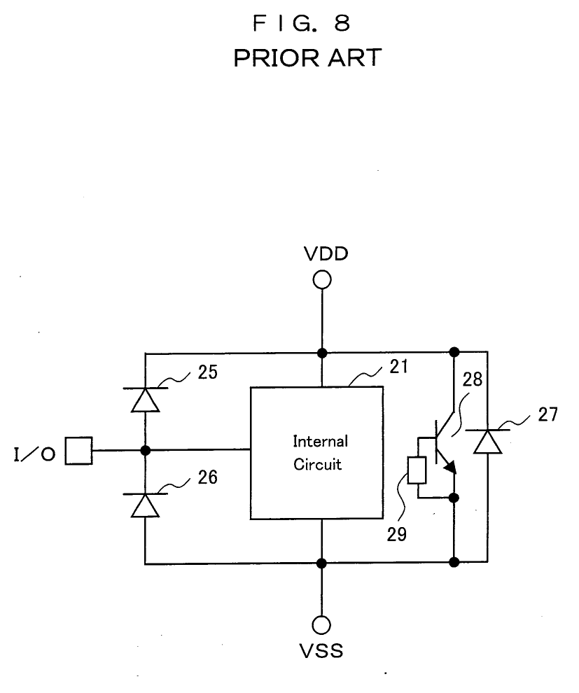

FIG. 9 is an illustration for describing the snapback characteristic of the related art;

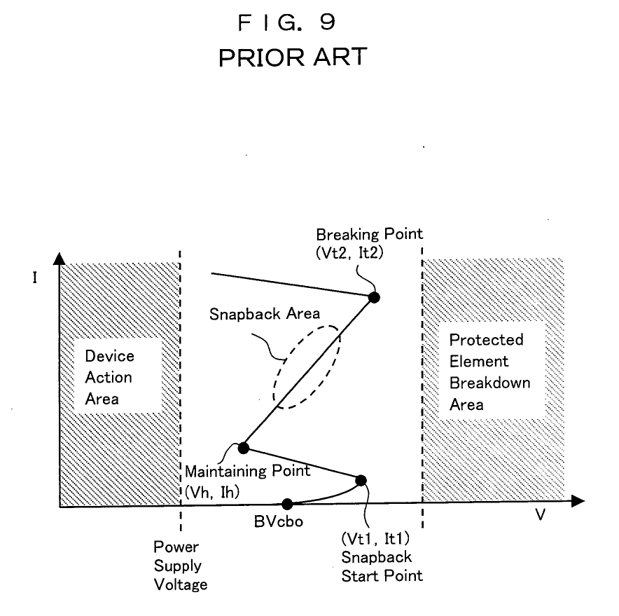

FIG. 10 is an illustration for showing the result of electric current simulation when TLP is applied to the electrostatic protective element of the related art; and

FIG. 11 is an illustration for showing the result of electric field simulation when TLP is applied to the electrostatic protective element of the related art.

In each drawing, the same reference numerals are applied to the same components.

### DETAILED DESCRIPTION OF THE PREFERRED EMBODIMENTS

In the followings, an electrostatic protective element of a semiconductor integrated circuit according to preferred embodiments of the present invention will be described by referring to the accompanying drawings.

### First Embodiment

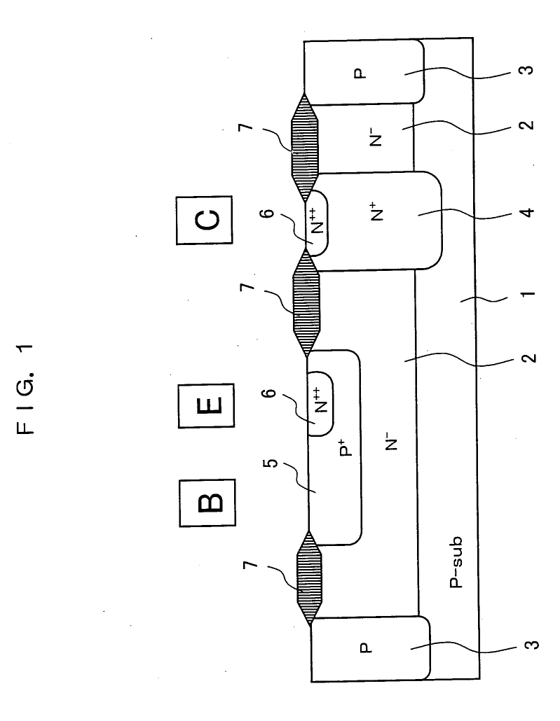

As shown in FIG. 1, the electrostatic protective element according to a first embodiment of the present invention has such a structure in which, in an NPN transistor which is formed with an N-type lightly-doped (N⁻) diffusion layer 2 serving as a collector layer being formed within a P-type substrate (silicon) 1, a P-type (P⁺) diffusion layer 5 serving as a base layer, and an N-type diffusion layer 6 serving as an emitter layer, a heavily-doped N-type diffusion layer 4 is formed in a contact area right under a collector electrode. Since the NPN transistor is in a structure with no embedded diffusion layer, the bottom face of the lightly-doped N-type diffusion layer 2 comes directly in contact with the P-type substrate 1 thereby forming pn junction between the collector and the substrate. The diffusion structure of the NPN transistor used in an internal circuit is not formed to have the heavily-doped N-type diffusion layer 4. Reference numeral 3 is an element isolation layer and 7 is a field oxide film. This electrostatic protective element corresponds to a 21V-system circuit to be protected.

The concentration profile from the surface of the substrate in the depth direction is as follows. The lightly-doped N-type diffusion layer 2 has the peak concentration of phosphorous of about 1×10¹⁶/cm³ at the position of about 0.35 μm deep, and is formed reaching the position of about 2.5 μm deep from the surface. The P-type diffusion layer 5 has the peak concentration of boron of about 1×10¹⁷/cm³ at the position of about 0.4 μm deep, and is formed reaching the position of about 0.8 μm deep from the surface. The N-type diffusion layer 6 has the peak concentration of phosphorous of about 1×10¹⁹/cm³ at the position of about 0.2 μm deep, and is formed reaching the position of about 0.35 μm deep from the surface. The heavily-doped N-type diffusion layer 4 right under the collector electrode has the peak concentration of phosphorous of about 1×10¹⁸/cm³ at the position of about 0.35 μm deep, and is formed reaching the position of about 0.3.5 μm deep from the surface.

As describe above, the heavily-doped N-type diffusion layer 4 is formed deeper than the lightly-doped N-type diffusion layer 2. In the meantime, the heavily-doped N-type diffusion layer 4 is disposed with a space of about 2 μm from the P-type diffusion layer 5 in the horizontal direction so that the breakdown voltage BVcbo can be used in the 21V system.

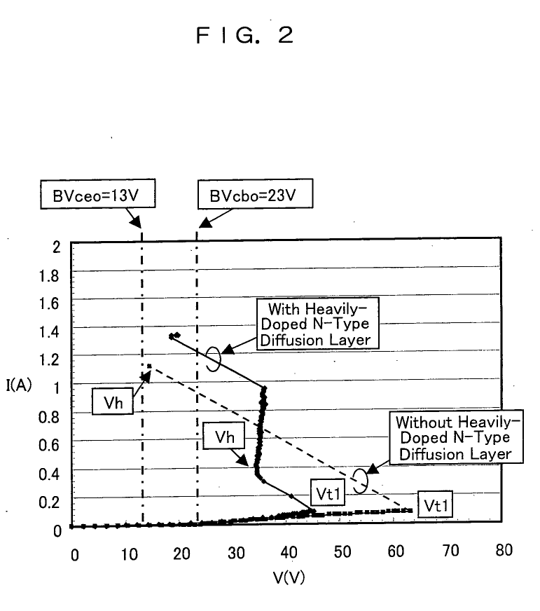

The effects of the present invention were verified by performing actual measurements and simulations by the Transmission Line Pulse in comparison of with and without the heavily-doped N-type diffusion layer 4. FIG. 2 shows the actually measured values of the snapback characteristic. As shown in FIG. 2, the snapback action start voltage Vt1 decreased from about 60V to about 46V. Meanwhile, the maintaining voltage Vh improved from about 13V to about 36V. It can bee seen from the result that the electrostatic protective element of this embodiment can be used in a circuit to be protected in which power supply to be used is 20V or more.

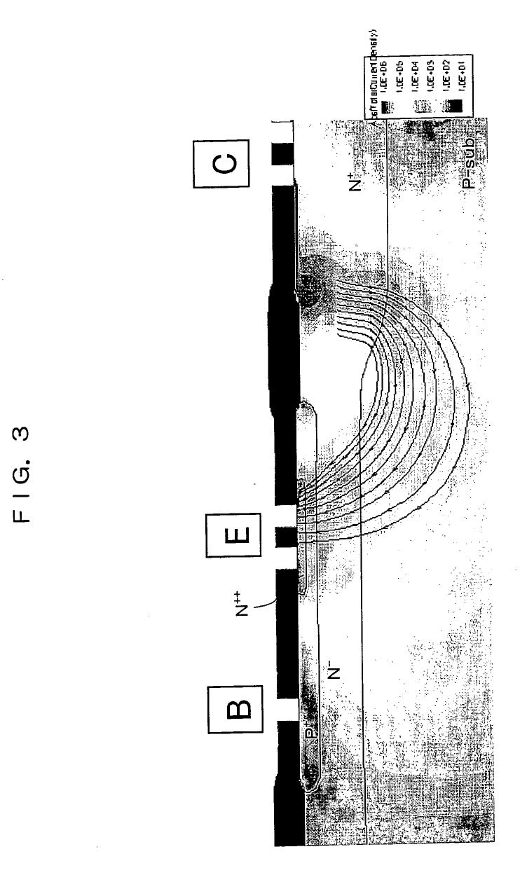

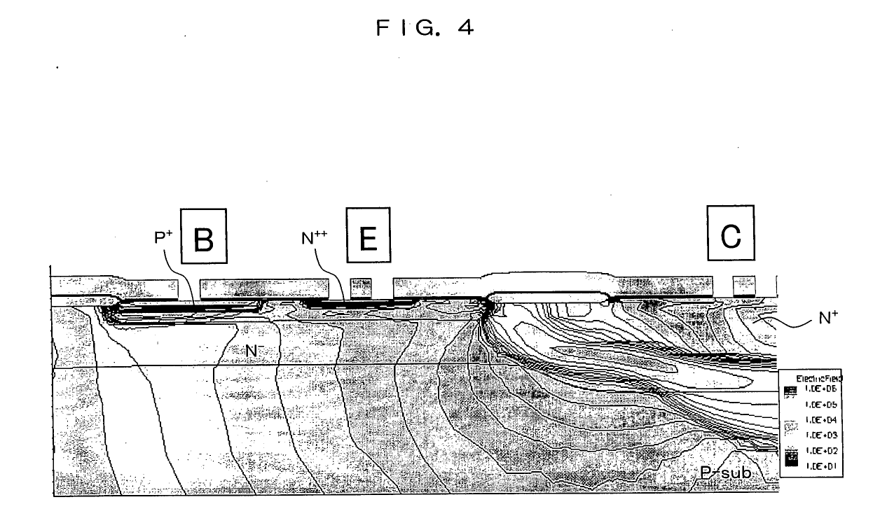

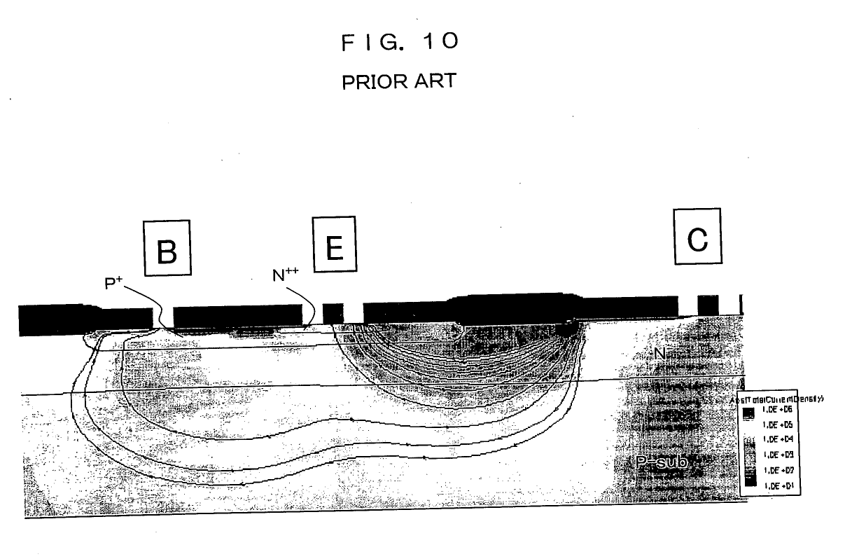

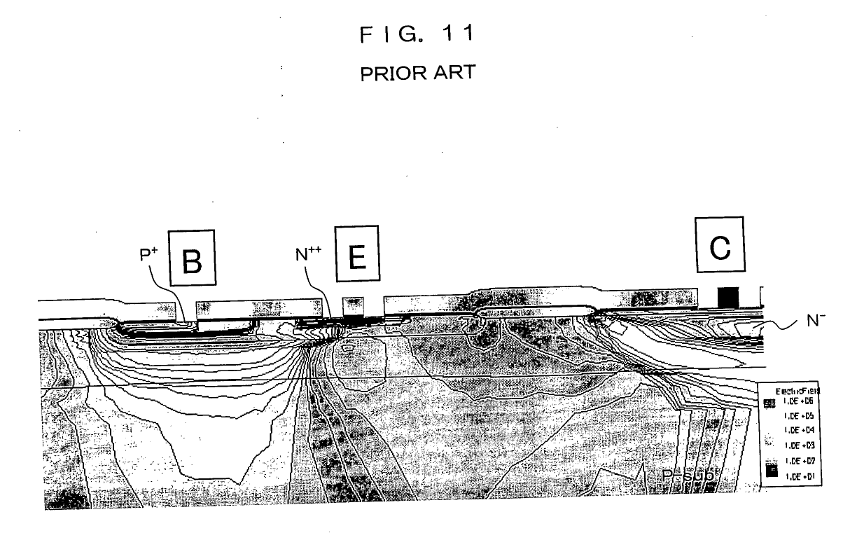

FIG. 3 and FIG. 4 show the results of the simulations of the snapback action of the electrostatic protective element according to this embodiment with the heavily-doped N-type diffusion layer 4, in which FIG. 3 is that of the electric current and FIG. 4 is that of the electric field. Meanwhile, FIG. 10 and FIG. 11 show the results of the simulations of the snapback action without the heavily-doped N-type diffusion layer 4, in which FIG. 10 is that of the electric field and FIG. 11 is that of the electric field.

In the case without the heavily-doped N-type diffusion layer 4, the electric current concentrates between CB junction and CE junction, and the electric field concentrates in the vicinity of the CB junction.

On the other hand, in the case of this embodiment which includes the heavily-doped N-type diffusion layer 4, the electric current flows from a collector to an emitter through the P-type substrate 1 as shown in FIG. 3, and the electric field concentrates in the vicinity of pn junction between the heavily-doped N-type diffusion layer 4 and the P-type substrate 1. It is considered that this phenomenon is caused due to expansion of the base width caused by Kirk Effect. When a plus surge voltage is applied to the collector, excess electrons are flown to the base from the emitter. Thus, holes in the base are radically increased by the electric charge neutrality condition within the base. Due to this increase, the base width is expanded. There is the heavily-doped N-type diffusion layer 4 in the horizontal direction so that the direction (in the depth direction from the substrate surface) of the lightly-doped N-type diffusion layer 2 interposed between the base layer (P-type diffusion layer 5) and the P-type substrate 1 is changed towards the P-type. Thus, the base layer reaches the P-type substrate 1. Thereby, the NPN transistor is to operate using the P-type substrate 1, the lightly-doped N-type diffusion layer 2, and the P-type diffusion layer 5 substantially as the base layer. With this, the base width becomes widened thereby decreasing the emitter ground current amplification factor h_{FE} of the NPN transistor under the transient phenomenon. Thus, the maintaining voltage Vh becomes boosted up.

As described above, it is possible to achieve the electrostatic protective element with the lower snapback action start voltage Vt1 and higher maintaining voltage Vh compared to those of the related art.

In this embodiment, the heavily-doped N-type diffusion layer 4 is formed deeper than the lightly-doped N-type diffusion layer 2. However, it may be formed nearly in the same depth as that of the lightly-doped N-type diffusion layer 2 as long as it enables to achieve the similar effects and is formed at least deeper than the P-type diffusion layer 5.

### Second Embodiment

Next, an electrostatic protective element of a semiconductor integrated circuit according to a second embodiment of the present invention will be described. This is aimed for improving the non-uniform actions.

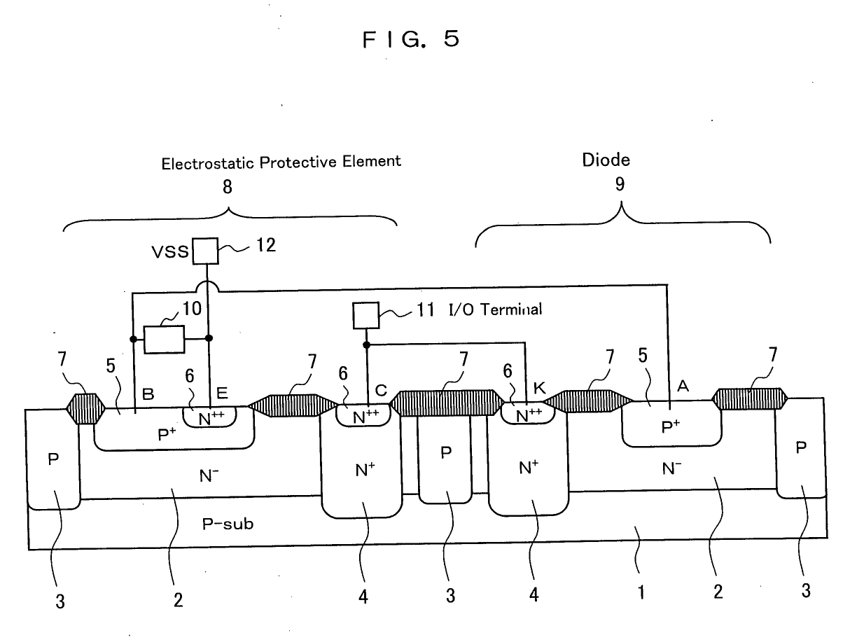

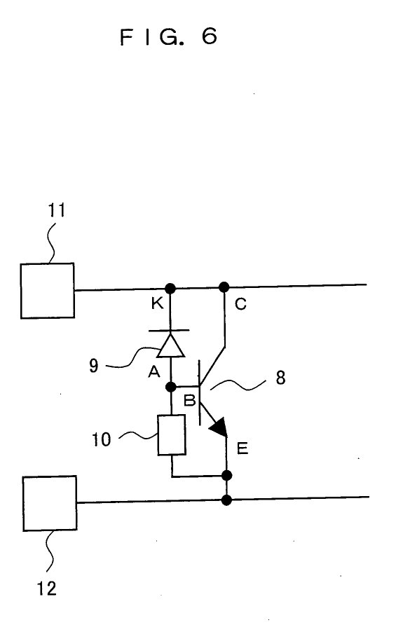

As shown in FIG. 5 and FIG. 6, an anode A of a diode 9 is connected to a base B of an electrostatic protective element 8, a cathode K of the diode 9 is connected to a collector C, and the base B is connected to an emitter E through a resistance 10. Further, the base B is connected to an input/output terminal 11 through the diode 9, the collector C is connected to the input/output terminal 11, and the emitter E is connected to a minimum potential terminal 12.

In general, when the ESD breakdown voltage Vt2 of the NPN transistor is lower than the snapback action start voltage Vt1, breakdown is caused at a voltage lower than the actual withstand voltage. Meanwhile, when the ESD braking voltage Vt2 is higher than the snapback action start voltage Vt1, breakdown is caused at the actual withstand voltage.

In the electrostatic protective element 8, a large number of NPN transistors are connected in parallel. Thus, at the time of snapback action, the transistors start to operate in order from the one whose base potential is closest to open. Thus, the lower ESD breakdown voltage Vt2 than the snapback action start voltage Vt1 means that not all the NPN transistors are in action. Inversely, higher ESD breakdown voltage Vt2 than the snapback action start voltage Vt1 means that all the NPN transistors are in action.

In the electrostatic protective element 8 of this embodiment, the ESD breakdown voltage Vt2 is lower than the snapback action start voltage Vt1. Thus, the electrostatic protective element 8 is likely to have non-uniform actions.

For a measure to improve it, as shown in FIG. 5, the diode 9 fabricated by the same diffusion layer as the collector layer and the base layer of the electrostatic protective element 8 is combined to form a compound type so as to lower the snapback action start voltage Vt1 than the ESD breakdown voltage Vt2. The same diffusion layer as the lightly-doped N-type diffusion layer 2 serving as an N⁻-type collector layer of the electrostatic protective element 8 is used for the cathode layer of the diode 9, and the same diffusion layer as the P-type diffusion layer 5 serving as the P⁺-type base layer of the electrostatic protective element 8 is used for the anode layer. Therefore, the diode 9 and the electrostatic protective element 8 break down almost at the same voltage. Further, by forming the heavily-doped N-type diffusion layer 4 of the electrostatic protective element 8 also in an contact area of the cathode layer of the diode 9, both break down at completely the same voltage. With this, the electric current flown into the base B becomes twice as much compared to the case of having no diode 9. Thus, the snapback action can be induced still faster.

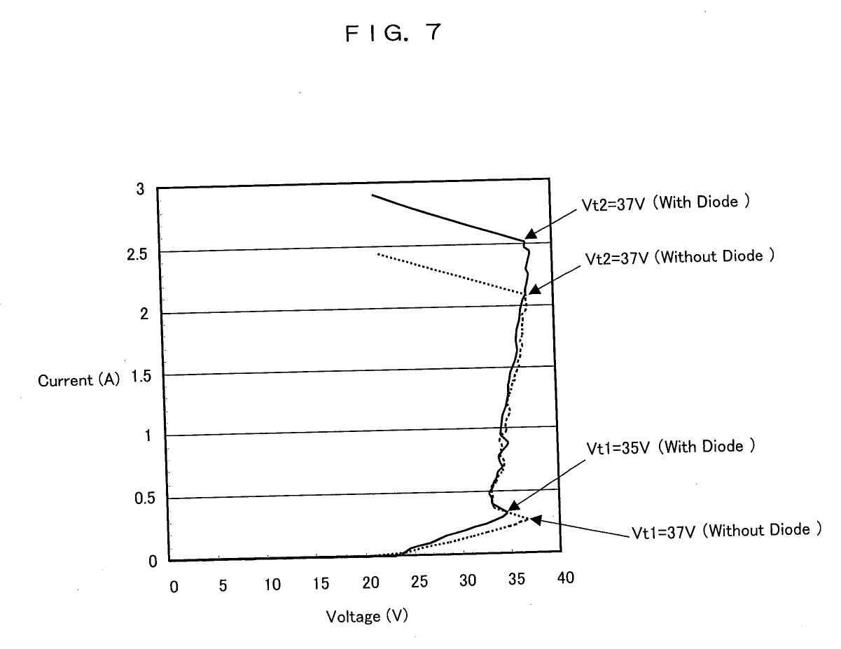

FIG. 7 shows the comparison of the snapback characteristics in the cases of with and without the diode 9. In the case without the diode 9, the snapback action start voltage Vt1 is about the same as the ESD breakdown voltage Vt2. Thus, the snapback action becomes non-uniform.

In the meantime, in the case with the diode 9, the snapback action start voltage Vt1 is lower than the ESD breakdown voltage Vt2 by about 2V. Thus, it is possible to perform the uniform snapback actions. With this, it is possible to suppress the dispersions in the ESD breakdown resistance It2. Further, by the improved uniformity, the capacity of the ESD breakdown resistance It2 of the electrostatic protective element itself can be brought out. Thus, it is expected to improve the ESD breakdown resistance It2 by about 20%.

As described above, in comparison to the first embodiment, this embodiment enables to promote the uniform operation of the electrostatic protective element, to decrease the dispersions in the ESD breakdown resistance It2 of the electrostatic protective element itself and, further, to improve the ESD breakdown resistance.

In this embodiment, the compound-type electrostatic protective element protects the input/output terminal 11 connected to the internal circuit. However, the same effect can be attained when it is used for protecting a power supply terminal.

The embodiments of the present invention can be applied in the same manner to the case where the polarities of the diffusion layer forming the electrostatic protective element are opposite.

The present invention is not limited to the above-described embodiments but various modifications are possible within the spirit and broad scope of the appended claims.

As has been described in detail, with the present invention in which the heavily-doped fourth diffusion layer is formed, it is possible to achieve the electrostatic protective element with the lower snapback action start voltage Vt1 and the higher maintaining voltage Vh compared to those of the related art.

In addition, by combining a diode and a resistance, it is possible to decrease the snapback action start voltage Vt1 while keeping the maintaining voltage Vh thereby enabling to decrease the dispersions in the ESD breakdown resistance It2 and to further improve the ESD breakdown resistance.

As described above, the present invention is effective as an art for improving the electrostatic protection effect for a circuit to be protected in a high-breakdown-strength semiconductor integrated circuit and the like.

What is claimed is:

1. An electrostatic protective element of a semiconductor integrated circuit, which is formed of a bipolar transistor, said electrostatic protective element comprising:
a second-conductive-type and lightly-doped first diffusion layer to be a collector, which is formed to be in contact with a first conductive type semiconductor substrate;
a first-conductive-type second diffusion layer to be a base, which is formed on said first diffusion layer;
a second-conductive-type third diffusion layer to be an emitter, which is formed on said second diffusion layer; and
a second-conductive-type and heavily-doped fourth diffusion layer, which is formed deeper than said second diffusion layer in a contact area of said first diffusion layer.

2. The electrostatic protective element of a semiconductor integrated circuit according to claim 1, further comprising:
a diode whose anode is connected to said base of said bipolar transistor and whose cathode is connected to said collector of said bipolar transistor; and
a resistance connected between said base and said emitter of said bipolar transistor,
said electrostatic protective element being formed in a compound type having a combination of said bipolar transistor, said diode, and said resistance.

3. The electrostatic protective element of a semiconductor integrated circuit according to claim 1, wherein said fourth diffusion layer is formed to be deeper or almost in a same depth with respect to said first diffusion layer.

4. The electrostatic protective element of a semiconductor integrated circuit according to claim 2, wherein: said base of said bipolar transistor is connected to an input/output terminal or a power supply terminal of a circuit to be protected through said diode; said collector of said bipolar transistor is connected to said input/output terminal or said power supply terminal; and said emitter of said bipolar transistor is connected to a minimum potential terminal of said circuit to be protected.

5. The electrostatic protective element of a semiconductor integrated circuit according to claim 2, wherein said diode is comprise of said first diffusion layer to be a cathode and said second diffusion layer to be an anode.

6. The electrostatic protective element of a semiconductor integrated circuit according to claim 5, wherein said diode comprises said heavily-doped fourth diffusion layer in said contact area of said first diffusion layer.
